(19) United States
(12) Patent Application Publication
(10) Pub. No.: US 2012/0043125 A1
(43) Pub. Date: Feb. 23, 2012

(54) CIRCUIT BOARDS, METHODS OF FORMING THE SAME AND SEMICONDUCTOR PACKAGES INCLUDING THE SAME

(76) Inventors: Taehoon Kim, Seongnam-si (KR); Jonggi Lee, Yongin-si (KR); Seungduk Baek, Hwaseong-si (KR)

(21) Appl. No.: 13/193,699

(22) Filed: Jul. 29, 2011

(30) Foreign Application Priority Data
Aug. 23, 2010 (KR) 10-2010-0081614

(51) Int. Cl. H05K 1/02; H05K 3/10

(52) U.S. Cl. 174/259; 29/846

(57) ABSTRACT

Provided is a method of forming a circuit board including an adhesion portion. The method may include forming a mask pattern including an opening on a board; performing a surface treatment process at a bottom of the opening; combining a linker with the surface on which a surface treatment process is performed; and forming a metal pattern combined with the linker in the opening.

### CROSS-REFERENCE TO RELATED APPLICATIONS

This U.S. non-provisional patent application claims priority under 35 U.S.C. §119 to Korean Patent Application No. 10-2010-0081614, filed on Aug. 23, 2010, the entire contents of which are hereby incorporated by reference.

### BACKGROUND

The present disclosure herein relates to circuit boards, methods of forming the same and semiconductor packages including the same, and more particularly, to a circuit board including an adhesion portion, a method of forming the same and a semiconductor package including the same.

As the use of electronic devices increases, a demand for a low cost electronic device having high performance, high quality and portability is increasing. Various studies of parts constituting an electronic device that can satisfy those requirements are being performed. A circuit board may be used in an electronic device for various uses and thereby it may be used as one of the important parts in an electronic device.

To satisfy those requirements for an electronic device, the circuit board should embody a fine pattern reproducibly at a low cost. Since equipment and raw materials of high cost are often used to embody a fine pattern reproducibly, the manufacturing cost increases. Furthermore, pollution problems may occur due to the raw materials used to form a metal pattern. Thus, various studies of manufacturing technology to embody a fine pattern reproducibly at a low cost are being performed.

### SUMMARY

Embodiments disclosed herein provide a method of forming a circuit board. The method may include forming a mask pattern including an opening on a board; performing a surface treatment process at a bottom of the opening; combining a linker with the surface on which a surface treatment process is performed; and forming a metal pattern combined with the linker in the opening.

Embodiments also provide a circuit board. The circuit board may include a board; an adhesion portion comprising functional group and a linker, the adhesion portion being disposed on the board; and a metal pattern disposed on the adhesion portion, wherein the metal pattern is combined with the linker of the adhesion portion.

Embodiments also provide semiconductor package. The semiconductor package may include a circuit board; and a semiconductor chip mounted on the circuit board. The circuit board comprises an adhesion portion which is disposed on the board and comprises a compound with which functional group and a linker are combined and a metal pattern disposed on the adhesion portion and combined with the linker on the adhesion portion.

### BRIEF DESCRIPTION OF THE FIGURES

The foregoing and other features and advantages of the embodiments disclosed herein will be apparent from the more particular description of exemplary aspects of the embodiments, as illustrated in the accompanying drawings in which like reference characters refer to like parts throughout the different views. The drawings are not necessarily to scale, emphasis instead being placed upon illustrating the principles of the disclosure. In the drawings, the thickness of layers and regions are exaggerated for clarity.

FIG. 1 is a flow chart for explaining a method of forming a circuit board in accordance with an exemplary embodiment.

FIGS. 2 through 6 are cross sectional views for explaining a method of forming a circuit board in accordance with an exemplary embodiment.

FIGS. 7A through 7C are cross sectional views for explaining a method of forming a circuit board in accordance with another exemplary embodiment.

FIG. 8 is a cross sectional view for explaining a semiconductor package including a circuit board formed according to another exemplary embodiment.

### DETAILED DESCRIPTION OF THE EMBODIMENTS

Various embodiments will be described below in more detail with reference to the accompanying drawings. The embodiments may, however, be embodied in different forms and should not be construed as limited to the embodiments set forth herein.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present.

Embodiments may be described with reference to cross-sectional illustrations, which are schematic illustrations of idealized embodiments. As such, variations from the shapes of the illustrations, as a result, for example, of manufacturing techniques and/or tolerances, are to be expected. Thus, embodiments should not be construed as limited to the particular shapes of regions illustrated herein, but are to include deviations in shapes that result from, e.g., manufacturing. For example, a region illustrated as a rectangle may be implemented with rounded or curved features. Thus, the regions illustrated in the figures are schematic in nature and are not intended to limit the scope of the present invention.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

(A Method of Forming a Circuit Board)

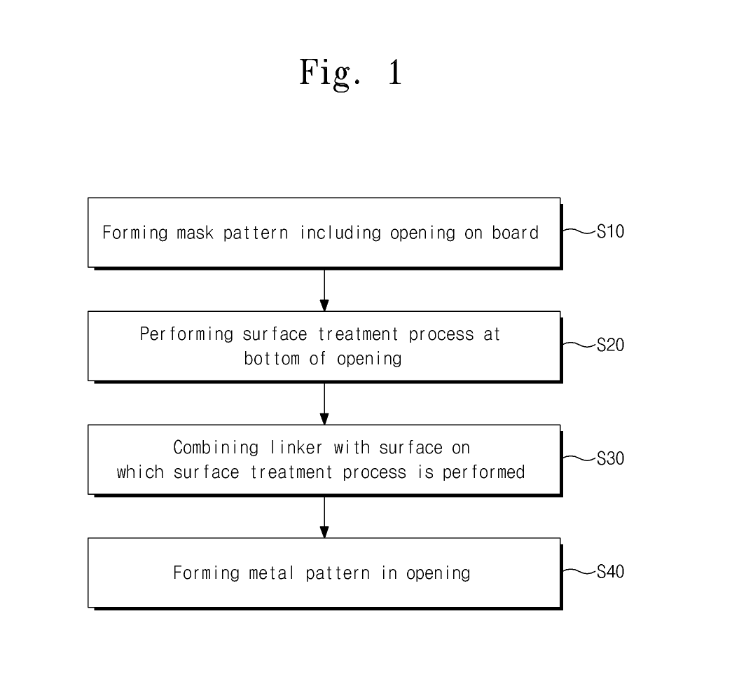

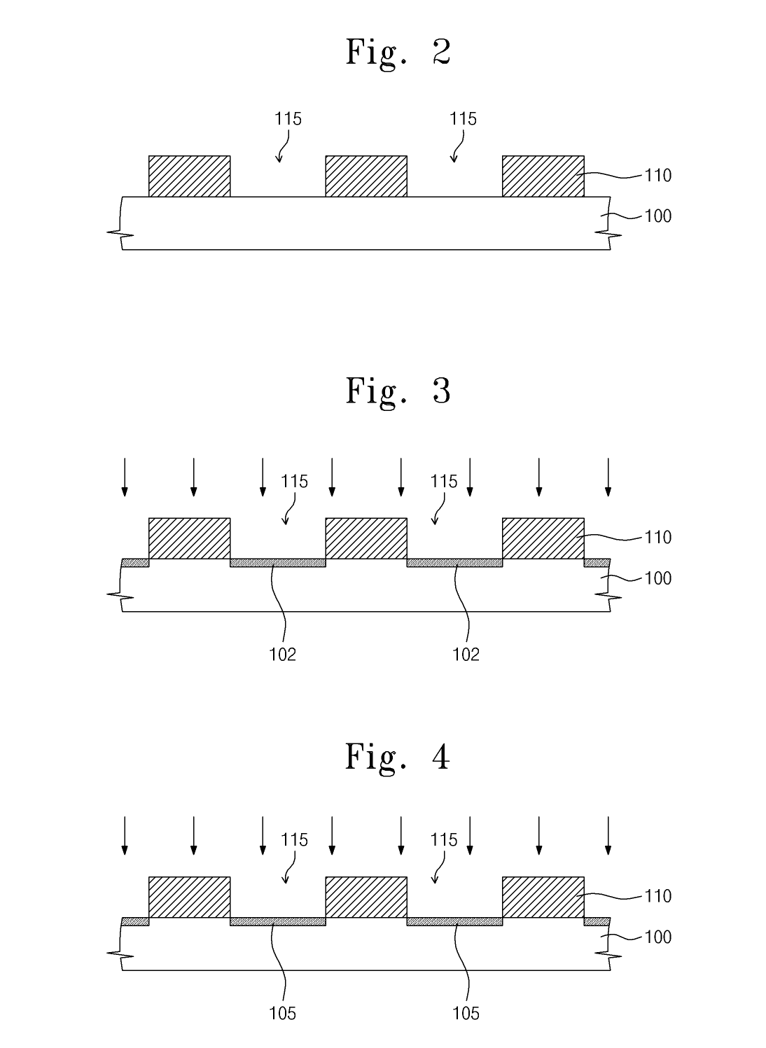

Hereinafter, a method of forming a circuit board in accordance with an exemplary embodiment is described. FIG. 1 is a flow chart for explaining a method of forming a circuit board in accordance with an exemplary embodiment. FIGS. 2 through 6 are cross sectional views for explaining a method of forming a circuit board in accordance with an exemplary embodiment.

Referring to FIGS. 1 and 2, a mask pattern 110 having an opening 115 may be formed on a board 100 (S10). A bottom of the opening 115 may include a highly polymerized compound. According to an embodiment, a top surface of the board 100 may be exposed by the opening 115. In this case, the bottom of the opening 115 may be defined by the top surface of the board 100. The board 100 may include, for example, an organic material, such as a highly polymerized compound. For example, the board 100 may be a polyimide or other suitable polymer material.

The mask pattern 110 may be formed of different material from the bottom of the opening 115. In one embodiment, the mask pattern 110 may be formed by a print method. For example, the mask pattern 110 may be formed by an imprint process or a roll to roll print process.

Hereinafter, a method of forming the mask pattern 110 using an imprint process is described. A mask film may be formed on a front side of the board 100. The mask film may include, for example, sclerogenic material. A mold is placed on the mask film, and then pressure is put on the mold to form a pattern. After that, the pattern is hardened to form the mask pattern 110. The hardening process may be performed, for example, by at least one of a hot air drying, an infrared light source, and an ultraviolet light source.

Hereinafter, forming the mask pattern 110 using a roll to roll print process is described. In the case that the mask pattern 110 is formed by a roll to roll print process, a mask film may not be formed on the board 100. After filling a print ink in a roller for a roll to roll print, a pattern may be printed on the board using the roller for a roll to roll print. After that, the printed pattern is hardened to form the mask pattern 110. The print ink may include, for example, sclerogenic material. The hardening process may be performed, for example, by at least one of a hot air drying, an infrared light source, and an ultraviolet light source.

According to certain embodiments, since the mask pattern 110 is formed by a print method, an exposure process is unnecessary, so the mask pattern 110 may be formed without high priced equipment for an exposure process. As a result, a manufacturing cost of the circuit board may be reduced.

Referring to FIGS. 1 and 3, a surface treating process may be performed at the bottom of the opening 115 (i.e., a top surface of the board 100) to form a surface treatment portion 102. The surface treating process may use, for example, an alkali solution. For example, in one embodiment, when the surface treating process is performed, the alkali solution is provided to the bottom of the opening 115 and thereby the alkali solution and a highly polymerized compound of the bottom of the opening 115 may react to each other to form the surface treatment portion 102. For example, the alkali solution may be potassium hydroxide (KOH). Many other suitable alkali solutions may also be used. In the case that the board 100 is exposed by the opening 115, the surface treatment portion 102 may be formed in a surface portion of the board 100 exposed by the opening 115.

A highly polymerized compound included in the bottom of the opening 115 may react to the alkali solution to form a compound having functional group. Thus, the surface treatment portion 102 may include a compound including the functional group. A surface of the mask pattern 110 may include little functional group. After the surface treating process is performed, a content ratio of functional group in the surface treatment portion may be much greater than a content ratio of functional group in the surface of the mask pattern 110. According to an embodiment, the content ratio of functional group in the surface of the mask pattern 110 may be almost zero.

Since the surface treatment portion 102 includes the functional group, it may have a high reactivity as compared with the bottom of the opening 115 of before the surface treating process is performed. The surface treatment portion 102 may also have a very high reactivity as compared with the surface of the mask pattern 110. For example, the functional group may be a carboxyl group.

Referring to FIGS. 1 and 4, a linker may be combined with the surface treatment portion 102 to form an adhesion portion 105 (S30). The linker may be combined with the functional group included in the surface treatment portion 102. The linker may be a compound including, for example, a thiol group, an isocyanide group, an amino group or a phosphate group. For example, the linker may be a thiol-silane. A process combining the functional group included in the surface treatment portion 102 with the linker may be performed in an organic solvent. For example, the linker may be combined with the functional group by providing an organic solvent including the linker to the surface treatment portion 102. The linker may be easily combined with the surface treatment portion 102 by the functional group included in the surface treatment portion 102.

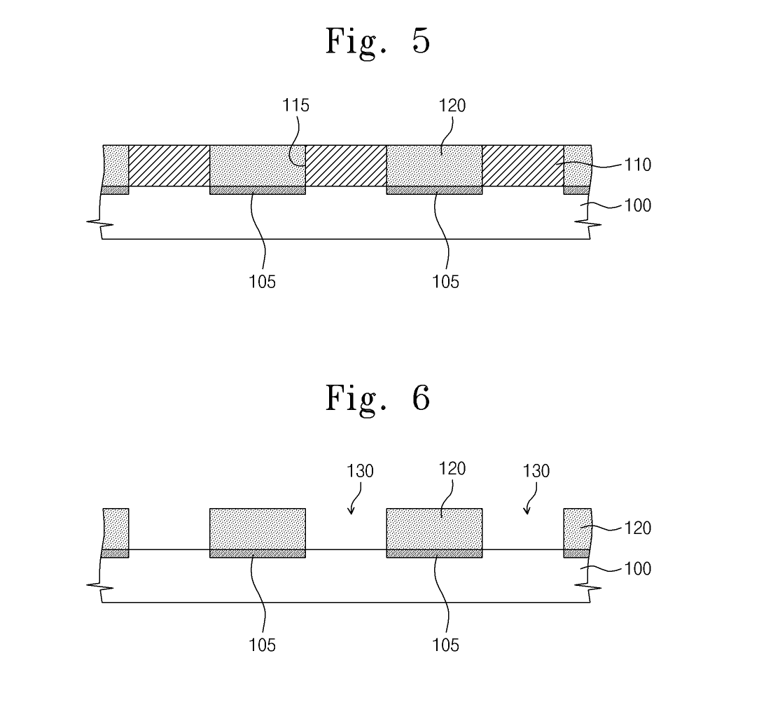

Referring to FIGS. 1 and 5, a metal pattern 120 combined with the linker included in the adhesion portion 105 may be formed on the board 100 (S40). The metal pattern 120 may be formed in the opening 115 by a metal growth process. The metal growth process may be performed by providing a solution including a precursor to the adhesion portion 105 and providing a reducing agent to the solution including the precursor. However, the present inventive concept is not limited thereto. According to an embodiment, the solution including the precursor and the reducing agent may be provided to the adhesion portion 105 at the same time.

The linker included in the surface treatment portion 102 may be combined with a metal element included in the precursor during the metal growth process. The linker may assist chemisorption of the metal element included in the precursor. For example, when the linker is thiol-silane, a sulfur element included in the thiol-silane may easily react to the metal element included in the precursor. Thus, the metal element may be combined with the sulfur element. When the linker includes isocyanide group, amino group or phosphate group, the metal element may be combined with a phosphorus element or a nitride element. As a result, the linker serves as a cohesion enhancer that provides a greater amount of cohesiveness between board 100 and a later formed metal pattern 120 than there would be between board 100 and a later formed metal pattern without the linker. The precursor may include a metal ion. For example, the precursor may be potassium tetrachloroaurate (KAuCl₄), tetracholoroauric acid (HAuCl₄) or silver nitrate (AgNO₃). The reducing agent may rapidly release electrons to reduce the precursor. For example, the reducing agent may be sodium borohydride (NaBH₄). If adding sodium borohydride (NaBH₄) which is a reducing agent to potassium tetrachloroaurate (KAuCl₄) which is a precursor, a metal ion included in the potassium tetrachloroaurate (KAuCl₄) may be reduced to form a gold aggregate. In one embodiment, the linker may have a high affinity with respect to a metal ion and a metal particle, the gold aggregate may be rapidly adsorbed onto the linker of the adhesion portion 105 to grow the metal pattern 120.

The metal pattern 120 may include, for example, at least one of silver (Ag), gold (Au), copper (Cu) or platinum (Pt). Since the metal pattern 120 is grown on the adhesion portion 105 by reduction and adsorption of a metal ion, a top surface of the metal pattern 120 may be formed to be higher than a bottom surface of the mask pattern 110. A height of the top surface of the metal pattern 120 may be controlled depending on a kind of a precursor and a reducing agent used in the metal growth process, the amount of the precursor and the reducing agent and a reaction time of the metal growth process.

Referring to FIG. 6, the mask pattern 110 on the board 100 may be removed. The mask pattern 110 may be removed by a selective etching process. For example, the mask pattern 110 may be removed by a wet etching process having an etching selectivity with respect to the metal pattern 120.

According to the method described above, the metal pattern 120 may be selectively grown in the opening 115. In the case that a metal film is deposited on a front side of the board 100, and then a metal pattern is formed by etching a portion of the deposited metal film, pollutant may occur due to a reaction of the metal film and an etching solution, thereby causing a failure of the circuit board. Also, in an etching process, a side of the metal pattern may be corroded by an etching solution and thereby problems such as undercut or thinning may occur. According to the aforementioned embodiments, since the metal pattern 120 may be selectively formed without performing an etching process, the metal pattern 120 may be formed without using a corrosive etching solution used in an etching process. Thus, pollutants that may occur during an etching process may be minimized. Since pollutants that may occur during an etching process may be minimized, a circuit board having improved reliability and characteristic may be embodied.

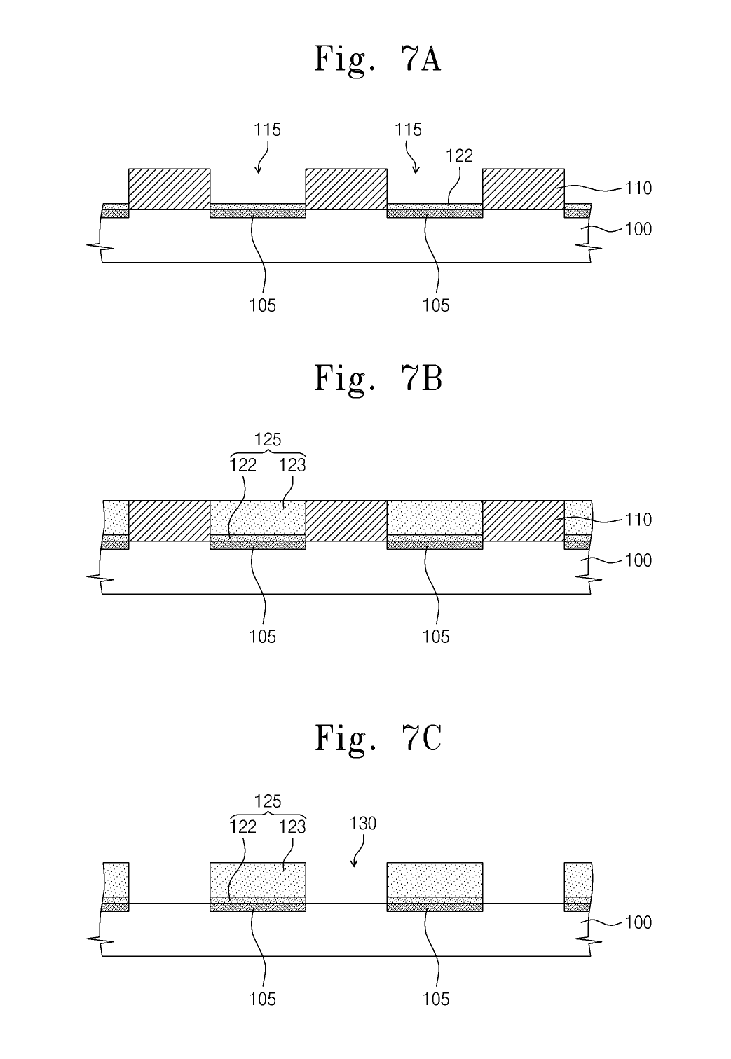

Hereinafter, a method of forming a circuit board in accordance with another embodiment is described with reference to FIGS. 7A through 7C. The method may include the methods described with reference to FIGS. 2 through 4. FIGS. 7A through 7C are cross sectional views for explaining a method of forming a circuit board in accordance with another embodiment.

Referring to FIGS. 7A and 7B, a metal pattern 125 combined with a linker included in the adhesion portion 105 may be formed in the opening 115 (S40). According to an embodiment, the metal pattern 125 may include a nano particle layer 122 combined with the linker and a bulk layer 123 formed by adsorbing metal ions onto the nano particle layer 122.

Referring back to FIG. 7A, the nano particle layer 122 may be formed by adsorbing nano particles onto the linker included in the adhesion portion 105. The nano particle may include, for example, at least one of silver (Ag), gold (Au), copper (Cu) or platinum (Pt). For example, the nano particle may be a gold nano particle.

The nano particle layer 122 may be formed using a nano particle formed in a state of colloid. The nano particle, after heating a solution including a precursor, may be formed by providing a reducing agent to the solution. The precursor may include a metal ion. For example, the precursor may include at least one of silver (Ag), gold (Au), copper (Cu) or platinum (Pt).

In an embodiment, the nano particle may be a gold nano particle. In this case, the functional group may be potassium tetrachloroaurate (KAuCl₄). A heating temperature of potassium tetrachloroaurate (KAuCl₄) may be 80 100 and the reducing agent added to the solution may be sodium citric-acid (Na₃C₆H₅O₇). A grading of the nano particle may be 15 nm 40 nm and a size distribution of the nano particle may be 20%.

The nano particle of a colloid state may be provided to the adhesion portion 105 including the linker, and then the nano particle may be combined with the linker to form the nano particle layer 122. Since the linker has a very high affinity with respect to the nano particle including metal, the nano particle may be rapidly adsorbed onto the linker.

Referring back to FIG. 7B, the metal pattern 125 may be formed by growing the bulk layer 123 on the nano particle layer 122. The bulk layer 123 may include, for example, at least one of silver (Ag), gold (Au), copper (Cu) or platinum (Pt). A process of growing the bulk layer 123 may be performed by providing a solution including a reducing agent to the nano particle layer 122, and then providing a precursor to the solution including the reducing agent. In one embodiment, the precursor includes metal. For example, the precursor may include at least one of silver (Ag), gold (Au), copper (Cu) or platinum (Pt). According to an embodiment, the bulk layer 123 may include gold (Au). In this case, the precursor and the reducing agent that are used to form the bulk layer 123 may be hydrogen tetrachloroaurate (HAuCl₄) and hydroxylamine hydrochloride (NH₂OH HCL), respectively.

In the process of growing the bulk layer 123, the nano particle layer 122 may be used as a seed layer. According to an embodiment, the nano particle layer 122 and the bulk layer 123 may include different metals from each other. For example, the nano particle layer 122 may include a metal nano particle and the bulk layer 123 may include copper (Cu).

Since the metal pattern 125 is formed by adsorbing a metal particle onto the nano particle layer 122 formed on the adhesion portion 105 to grow the bulk layer 123, a top surface of the metal pattern 125 may be formed to be higher than a bottom surface of the mask pattern 110. A height of the top surface of the metal pattern 125 may be controlled depending on a kind of a precursor and a reducing agent used in the process of growing the bulk layer 123, the amount of the precursor and the reducing agent and/or a reaction time of the process of growing the bulk layer 123.

Referring to FIGS. 1 and 7C, the mask pattern 110 on the board 100 may be removed. The mask pattern 110 may be removed by a selective etching process. The mask pattern 110 may be removed by a wet etching process having an etching selectivity with respect to the metal pattern 125.

According to the method described above, the metal pattern 120 may be formed by forming the nano particle layer 122, and then selectively growing the bulk layer 123 on the nano particle layer 122. In the case that a metal film is deposited on a front side of the board 100, and then a metal pattern is formed by etching a portion of the deposited metal film, pollutants may occur due to a reaction of the metal film and an etching solution, thereby causing a failure of the circuit board. Also, in an etching process, a side of the metal pattern is corroded by an etching solution and thereby problems such as undercut or thinning may occur. According to the aforementioned embodiments, since the metal pattern 125 may be selectively formed without performing an etching process, the metal pattern 125 may be formed without using a corrosive etching solution used in an etching process. Thus, pollutants that may occur during an etching process may be minimized. Since pollutants that may occur during an etching process may be minimized, a circuit board having improved reliability and characteristics may be embodied.

(Circuit Board)

Hereinafter, a circuit board in accordance with an exemplary embodiment is described. FIG. 6 is a cross sectional view for explaining a circuit board formed in accordance with an exemplary embodiment.

Referring to FIG. 6, a metal pattern 120 including an opening 130 may be disposed on a board 100. According to an embodiment, a portion of the board 100 may be exposed by the opening 130. In the case that a portion of the board 100 is exposed by the opening 130, the board 100 may include a highly polymerized compound. For example, the board 100 may be a polyimide.

An adhesion portion 105 including a linker combined with the metal pattern 120 may be disposed in the board 100. The adhesion portion 105 may be formed by after covering a bottom of the opening 130 with a mask pattern, performing a surface treatment process on a top surface of the exposed board 100 to form a compound including functional group on the top surface of the exposed board 100, and then combining the linker with the board 100 on which the surface treatment process is performed. The surface treatment process may be performed while an alkali solution is provided on the top surface of the board 100 exposed by the mask pattern and then a highly polymerized compound included in the board 100 and the alkali solution react to each other. For example, the alkali compound may be potassium hydroxide (KOH). Since the top surface of the board 100 on which the surface treatment process is performed includes functional group, it may have a higher reactivity than the top surface of the board 100 on which the surface treatment process is not performed. For example, the functional group may be carboxyl group.

An organic solvent including the linker may be provided on the top surface of the board 100 including the functional group and the linker may be combined with the functional group. By the functional group included in the adhesion portion 105, the linker may be easily combined with the top surface of the board 100 on which the surface treatment process is performed. The linker included in the adhesion portion 105 may have a very high affinity with a metal ion or metal particles. Thus, a metal ion or metal particles may be rapidly adsorbed onto the linker. The linker may be a compound including, for example, a thiol group, a isocyanide group, an amino group or a phosphate group. For example, the linker may be thiol-silane.

The metal pattern 120 may be formed by performing processes of reduction and adsorption of a metal ion on the linker included in the adhesion portion 105 in the board 100. Thus, the metal pattern 120 may be formed to have a shape of being combined with the linker. The meal pattern 120 may include, for example, at least one of silver (Ag), gold (Au), copper (Cu) or platinum (Pt).

Unlike the elements illustrated in FIG. 6, a polymer film may be further disposed on the board 100 and the adhesion portion 105 may be disposed in the top surface of the polymer film. In this case, the metal pattern 120 may be formed to be combined with the linker included in the adhesion portion 105 disposed in a top surface of the polymer film.

Hereinafter, a circuit board in accordance with another embodiment is described. For a brief description, the description of the common features already discussed in the aforementioned embodiment is omitted. FIG. 7C is a cross sectional view for explaining a circuit board formed according to an exemplary embodiment.

Referring to FIG. 7C, a metal pattern 125 including an opening 130 may be disposed on a board 100. The opening 130 may be identical to an embodiment described above. The board 100 may also be identical to an embodiment described above.

An adhesion portion 105 that is in contact with the metal pattern 125 may be disposed in the board 100. The adhesion portion 105 may be identical to an embodiment described above.

In one embodiment, the metal pattern 125 may include a nano particle layer 122 and a bulk layer 123. The nano particle layer 122 may be formed by adsorbing a nano particle to a linker included in the adhesion portion 105. Thus, the nano particle layer 122 may be formed to have a shape of being combined with the linker included in the adhesion portion 105. In one embodiment, a nano particle included in the nano particle layer 122 may include metal. For example, the nano particle may include at least one of silver (Ag), gold (Au), copper (Cu) or platinum (Pt).

The nano particle of a colloid state may be provided to the adhesion portion 105 including the linker, and then the nano particle may be adsorbed onto the linker to form the nano particle layer 122. Since the linker has a very high affinity with respect to the nano particle including metal, the nano particle may be rapidly adsorbed onto the linker.

A bulk layer 123 may be grown on the nano particle layer 122 to form the metal pattern 125. The bulk layer 123 may include, for example, at least one of silver (Ag), gold (Au), copper (Cu) or platinum (Pt).

The bulk layer 123 may be grown by providing a solution including a reducing agent onto the nano particle layer 122, and then providing a precursor to the solution including the reducing agent. However, the present inventive concept is not limited thereto. According to an embodiment, the solution including the precursor and the reducing agent may be provided to the adhesion portion 105 at the same time.

The precursor may include metal. For example, the precursor may include at least one of silver (Ag), gold (Au), copper (Cu) or platinum (Pt). According to an embodiment, the bulk layer 123 may include gold (Au). In this case, the precursor and the reducing agent that are used to form the bulk layer 123 may be hydrogen tetrachloroaurate (HAuCl₄) and hydroxylamine hydrochloride (NH₂OH HCL), respectively.

The nano particle layer 122 may be used as a seed layer in a process of growing the bulk layer 123. According to an embodiment, the nano particle layer 122 and the bulk layer 123 may include different metals from each other. For example, the nano particle layer 122 may include a nano particle and the bulk layer 123 may include copper (Cu).

A height of the top surface of the metal pattern 125 may be controlled depending on a kind of a precursor and a reducing agent used in the metal growth process, the amount of the precursor and the reducing agent and a reaction time of the metal growth process.

Unlike the elements illustrated in FIG. 7C, a polymer film may be further disposed on the board 100 and the adhesion portion 105 may be disposed in the top surface of the polymer film. In this case, the metal pattern 125 may be formed to be combined with the linker included in the adhesion portion 105 disposed in a top surface of the polymer film.

The circuit board in accordance with the disclosed embodiments is one of the parts constituting an electronic device and may be used in an electronic device in various ways. The circuit board in accordance with the disclosed embodiments may be used for a close combination between different constitution parts. For example, the circuit board may be used so that different constitution parts are redistributed to be closely combined with one another.

The circuit board in accordance with the disclosed embodiments may also be used as a board of a semiconductor package on which a semiconductor device is mounted. For example, a semiconductor device may be mounted on the circuit board in accordance with the exemplary embodiments and the semiconductor device and the circuit board may be closely combined with each other to form the semiconductor package.

(Semiconductor Package)

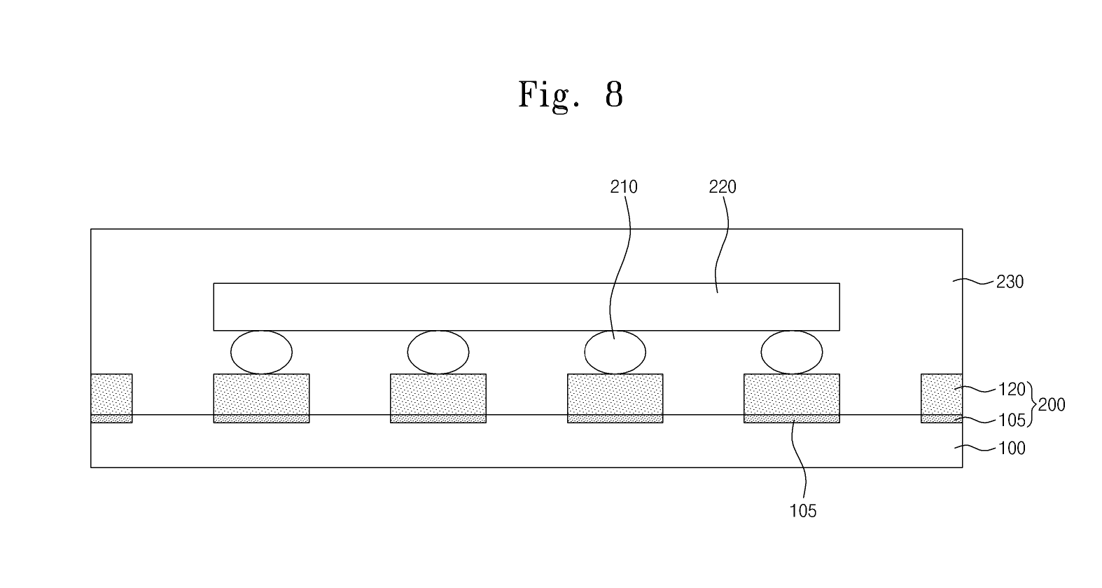

FIG. 8 is a cross sectional view for explaining a semiconductor package including a circuit board formed according to another exemplary embodiment.

Referring to FIG. 8, a circuit board 200 including a metal pattern 120 disposed on a board 100 is prepared. The circuit board 200 may be formed according to the aforementioned embodiments. Thus, the circuit board 200 may include an adhesion portion 105 that is in contact with the metal pattern 120 in the board 100. The adhesion portion 105 may include a compound in which functional group is combined with a linker.

A semiconductor chip 220 may be disposed on the circuit board 200. The semiconductor chip 220 may include a pad and/or a penetration electrode to be electrically connected to the circuit board 200.

The semiconductor package may further include a connection portion 210 to electrically connect the circuit board 200 and the semiconductor chip 220. The connection portion 210 may include, for example, at least one of a lead, a wire, a solder or a bump. The connection portion 210 may include metal. For example, the connection portion 210 may include gold (Au) and/or copper (Cu).

A mold portion 230 covering the semiconductor chip 220 may be disposed on the circuit board 200. The mold portion 230 may include a highly polymerized compound. The mold portion 230 may perform a function of protecting the semiconductor chip 220 on the circuit board 200.

As described above, the circuit board in accordance with the disclosed embodiments may form a metal pattern on the board using a surface treatment and a linker combination reaction. Thus, since a metal pattern can be formed without performing an exposure process and an etching process, it is not necessary to use high priced equipment, and therefore a manufacturing cost of the circuit board may be reduced.

What is claimed is:

1. A method of forming a circuit board comprising:
forming a mask pattern including an opening on a board;
performing a surface treatment process on a surface of the board at the bottom of the opening;
combining a linker with the surface on which the surface treatment process is performed; and
forming a metal pattern combined with the linker in the opening.

2. The method of claim 1, wherein the mask pattern is formed by an imprint process or a roll to roll print process.

3. The method of claim 2, wherein the surface of the board comprises a highly polymerized compound.

4. The method of claim 3, wherein the surface treatment process is performed on the surface of the board using an alkali compound.

5. The method of claim 4, wherein the surface of the board at which a surface treatment process is performed comprises a compound having carboxyl group.

6. The method of claim 1, wherein the linker is a compound comprising thiol group, isocyanide group, amino group or phosphate group.

7. The method of claim 1, wherein a top surface of the metal pattern is formed to be higher than a bottom surface of the mask pattern.

8. The method of claim 1, wherein the metal pattern is formed by a metal growth process and the metal growth process is performed using a solution comprising a precursor and a reducing agent.

9. The method of claim 1, wherein forming the metal pattern comprises:
forming a nano particle layer by adsorbing a metal nano particle onto the adhesion portion; and
growing a bulking layer on the nano particle layer.

10. The method of claim 9, wherein the metal nano particle is in a state of colloid and a grading of the metal nano particle is 15 nm 40 nm.

11. The method of claim 9, wherein the metal pattern is grown by a solution comprising a precursor and a reducing agent.

12. A circuit board comprising:
a board;
an adhesion portion comprising functional group and a linker, the adhesion portion being disposed on the board; and
a metal pattern disposed on the adhesion portion, wherein the metal pattern is combined with the linker of the adhesion portion.

13. The circuit board of claim 12, wherein the board is a circuit board comprising a highly polymerized compound.

14. The circuit board of claim 13, wherein the functional group is carboxyl group and the functional group is formed by performing a surface treatment process on a portion of the board using an alkali compound.

15. The circuit board of claim 12, wherein the linker is a compound comprising thiol group, isocyanide group, amino group or phosphate group.

16. A method of forming a metal pattern on a circuit board comprising:
providing a board comprised of an organic material;
forming a mask pattern including an opening exposing a portion of the board;
performing a surface treatment on the portion of the board exposed by the opening to form functional groups within the opening;
depositing a linking compound that connects to the functional groups;
depositing a metal, wherein the metal connects to the linking compound, so as to form a metal area within the opening in the mask pattern; and
removing the mask pattern leaving behind a metal pattern formed on the board.

17. The method of claim 16, wherein the board is comprised of polyimide, the surface treatment comprises an alkali compound, and the functional groups comprise carboxyl groups.

18. The method of claim 17, wherein the linking compound is a thiol-silane.

19. The method of claim 18, wherein the metal is connected to the linking compound by adding potassium tetrachloroaurate (KAuCl₄), tetracholoroauric acid (HAuCl₄) or silver nitrate (AgNO₃), and a reducing agent.

20. A method of forming a metal pattern on a circuit board comprising:
providing a board;
patterning a mask on the board;
performing a surface treatment on areas of the board not covered by the mask to form reactive areas on the board;
depositing a linking compound that connects to the reactive areas on the board;
depositing a metal, wherein the metal connects to the linking compound, so as to form metal areas on the board.
